(19) United States
(12) Patent Application Publication
(10) Pub. No.: US 2011/0235457 A1
(43) Pub. Date: Sep. 29, 2011

(54) SEMICONDCUTOR INTEGRATED CIRCUIT DEVICE

(75) Inventor: Yoshiharu Hirata, Kanagawa-ken (JP)

(73) Assignee: KABUSHIKI KAISHA TOSHIBA, Tokyo (JP)

(21) Appl. No.: 13/051,149

(22) Filed: Mar. 18, 2011

(30) Foreign Application Priority Data
Mar. 29, 2010 (JP) 2010-074138

(51) Int. Cl. G11C 5/14; G05F 1/10

(52) U.S. Cl. 365/226; 327/538

(57) ABSTRACT

According to one embodiment, a semiconductor integrated circuit device is provided. The semiconductor integrated circuit device is provided with a plurality of booster circuits, a regulator and a plurality of switches. Each of the booster circuit receives an input voltage, boosts the input voltage, and generates a boosted voltage having a different value. The regulator is capable of generating a plurality of dropped voltages by dropping each boosted voltage from the booster circuits. The switches are connected between the booster circuits and the regulator. The switches provide the boosted voltages outputted from the booster circuits selectively to the regulator as a power-supply voltage.

### CROSS-REFERENCE TO RELATED APPLICATION(S)

This application is based upon and claims the benefit of priority from the prior Japanese Patent Application No. 2010-74138, filed on Mar. 29, 2010, the entire contents of which are incorporated herein by reference.

### FIELD

Embodiments described herein relate generally to a semiconductor integrated circuit device provided with a regulator.

### BACKGROUND

A booster circuit and a regulator are provided in various kinds of semiconductor integrated circuit devices, e.g., semiconductor memory devices such as a NOR flash memory and a NAND flash memory. The booster circuit generates a boosted voltage by booster a power-supply voltage provided from an external power supply. The regulator generates a plurality of dropped voltages by dropping the boosted voltage. In the description below, a “regulator” means a circuit for generating a dropped voltage. A relatively high boosted voltage is provided to the regulator as a power-supply voltage.

In order to increase memory capacity of a semiconductor memory device, many products have been recently developed. In such products, each memory cell transistor has four values, i.e., multiple-value memory information of 2 bits or more. Such a semiconductor memory device having the multiple-value memory is provided with a plurality of booster circuits for generating boosted voltages having different values, which are used for reading data, writing data, erasing data, etc. When the semiconductor memory device is used for rewriting, writing verification, erasing verification, reading, etc. of data, the semiconductor memory device needs to have a larger number of dropped voltages having different values which are outputted from the regulators.

In addition, when a semiconductor memory device has various functions as described above, a booster circuit is used more frequently, which causes a problem that more power is consumed by the semiconductor memory device. Not only the regulator used in the semiconductor memory device but also a regulator used in a semiconductor integrated circuit device receive a relatively high boosted voltage as a power-supply voltage, and generate a dropped voltage which is lower than the boosted voltage. This causes a problem that an internal loss of the regulator increases.

### BRIEF DESCRIPTION OF THE DRAWINGS

FIG. 1 is a block diagram illustrating a schematic configuration of a semiconductor memory device according to a first embodiment;

FIG. 2 illustrates a relationship between threshold voltages, output signal levels and data of a memory cell transistor of the semiconductor memory device according to the first embodiment;

FIGS. 3A and 3B illustrate a booster circuit constituting the semiconductor memory device respectively;

FIG. 3C illustrates a circuit generating a plurality of voltages, which is included in each booster circuit of FIGS. 3A and 3B.

FIG. 4 is a circuit diagram illustrating a regulator of the semiconductor memory device;

FIG. 5 is a block diagram illustrating a schematic configuration of a semiconductor memory device according to the first comparative example;

FIG. 6 illustrates a relationship between input voltages and output voltages of the regulators shown in FIGS. 1 and 5;

FIG. 7 illustrates an internal loss of the regulator of the semiconductor memory device according to the first embodiment;

FIGS. 8A and 8B illustrate examples of data rewriting and data reading operation performed by the semiconductor memory device according to the first embodiment, respectively;

FIG. 9 illustrates change of a writing voltage during step-up writing performed by the semiconductor memory device according to the first embodiment;

FIG. 10 is a block diagram illustrating a schematic configuration of a semiconductor memory device according to a second embodiment;

FIG. 11 illustrates a relationship between threshold voltages, output signal levels and data of a memory cell of the semiconductor memory device according to the second embodiment;

FIG. 12 is a block diagram illustrating a schematic configuration of a semiconductor memory device according to a second comparative example;

FIG. 13 illustrates a relationship between input voltages and output voltages of the regulators shown in FIGS. 10 and 12; and

FIG. 14 illustrates an internal loss of the regulator of the semiconductor memory device according to the second embodiment.

### DETAILED DESCRIPTION

According to one embodiment, a semiconductor integrated circuit device is provided. The semiconductor integrated circuit device is provided with a plurality of booster circuits, a regulator and a plurality of switches.

Each of the booster circuit receives an input voltage, boosts the input voltage, and generates a boosted voltage having a different value. The regulator is capable of generating a plurality of dropped voltages by dropping each boosted voltage from the booster circuits. The switches are connected between the booster circuits and the regulator. The switches provide the boosted voltages outputted from the booster circuits selectively to the regulator as a power-supply voltage.

Hereinafter, further embodiments will be described with reference to the drawings.

In the drawings, the same or similar reference numerals denote the same portions respectively.

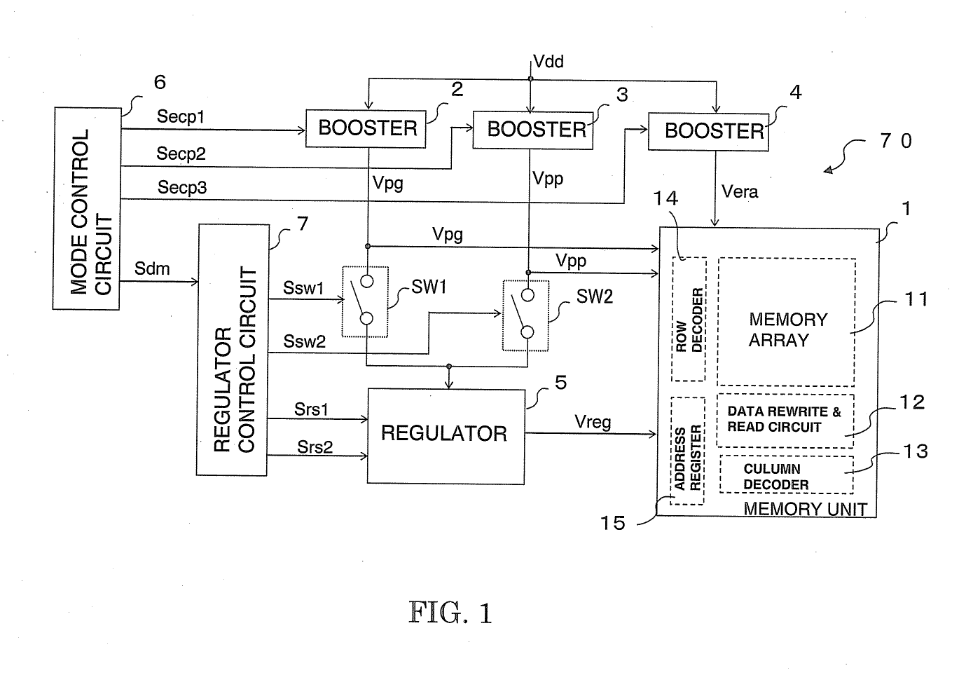

A semiconductor integrated circuit device of a first embodiment will be described with reference to FIGS. 1 to 5. The semiconductor integrated circuit device is a semiconductor memory device.

FIG. 1 is a block diagram illustrating a schematic configuration of a semiconductor memory device according to the first embodiment. In the embodiment, two booster circuits provide boosted voltages having different values. The boosted voltages are selectively inputted into a regulator via witches for dropping the respective voltages.

The regulator generates a plurality of dropped voltages. The dropped voltages are provided to a memory unit.

As illustrated in FIG. 1, a semiconductor memory device 70 is provided with a memory unit 1, booster circuits 2 to 4, a regulator 5, a mode control circuit 6, a regulator control circuit 7, and switches SW1, SW2.

The semiconductor memory device 70 is a NOR flash memory having memory cell transistors. Each of the memory cell transistors can store information of four values (2 bits).

The memory unit 1 is provided with a memory cell array 11, an address register 15, a row decoder 14, a column decoder 13, and a data rewriting and reading circuit 12. In the memory cell array 11, memory cell transistors storing data are arranged in a matrix. The address register 15 designates an address of a memory cell transistor. The row decoder 14 is connected to word lines (WL) of the memory cell array 11. The column decoder 13 is connected to bit lines (BL) of the memory cell array 11. The data rewriting and reading circuit 12 rewrites and reads data.

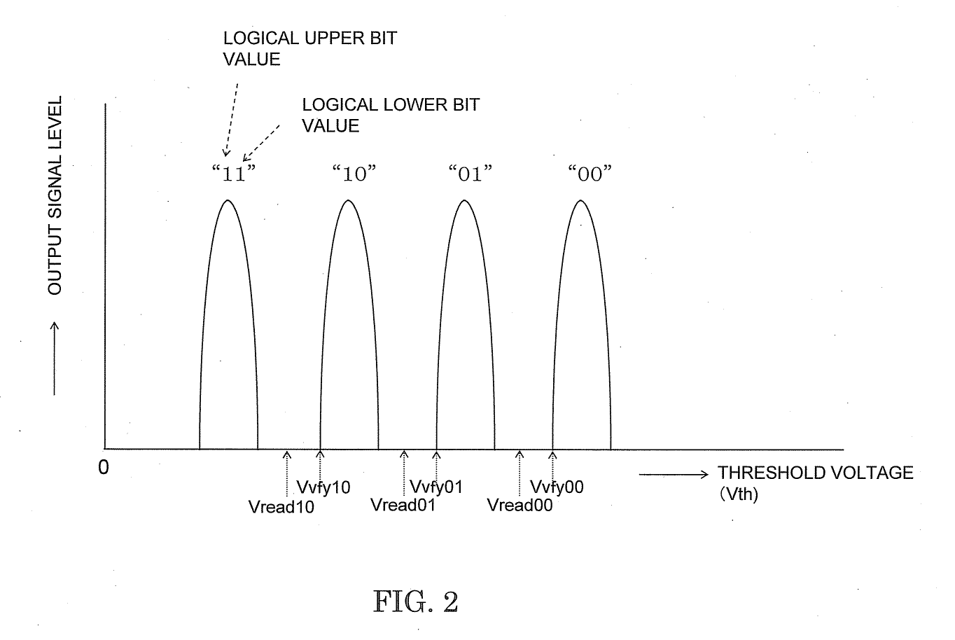

FIG. 2 illustrates a relationship between threshold voltages, output signal levels and data of a memory cell transistor provided in the memory cell array 11 according to the first embodiment. The memory cell transistor stores information of four values (2 bits), i.e., “11”, “10”, “01”, and “00”.

The information “11” is distributed within a range between a threshold voltage 0 (zero) and a reading voltage Vread10. For example, the information “11” has a range of threshold voltage from 1.2 to 2.0 V. The information “10” is distributed within a range between the reading voltage Vread10 and a reading voltage Vread01. The lowest value of the distributed range of the information “10” is equal to or more than a writing verification voltage Vvfy10. For example, the information “10” has a range of threshold voltage from 2.8 to 2.9 V. The information “01” is distributed within a range between the reading voltage Vread0l and a reading voltage Vread00. The lowest value of the distributed range of the information “01” is equal to or more than a writing verification voltage Vvfy01. For example, the information “01” has a range of threshold voltage from 3.6 to 3.7 V. The information “00” is distributed within a range more than the reading voltage Vread00. The lowest value of the distributed range of the information “00” is equal to or more than a writing verification voltage Vvfy00. For example, the information “00” has a range of threshold voltage from 4.5 to 5.5 V.

For example, the reading voltage Vread10 is set at 2.4 V. The reading voltage Vread01 is set at 3.2 V, for example. The reading voltage Vread00 is set at 4.0 V, for example. The writing verification voltage Vvfy10 is set at 2.8 V, for example. The writing verification voltage Vvfy01 is set at 3.6 V, for example. The writing verification voltage Vvfy00 is set at 4.5 V, for example.

The mode control circuit 6 generates control signals Secp1 to Secp3 for controlling the booster circuits 2 to 4 respectively, and generates an operation mode control signal Sdm. When the control signals Secp1 to Secp3 are in an enabling state, the booster circuits 2 to 4 operate respectively. When the control signals Secp1 to Secp3 are in a disabling state, the booster circuits 2 to 4 are turned off respectively.

The booster circuit 2 receives, as an input voltage, a power-supply voltage Vdd provided from the outside of the semiconductor memory device 70. When the control signal Secp1 is in an enabling state, the booster circuit 2 generates a boosted voltage Vpg obtained by booster the power-supply voltage Vdd. When the control signal Secp1 is in a disabling state, the booster circuit 2 stops operating. The power-supply voltage Vdd is set at a value in range from 1.8 V to 3.3 V, for example. The power-supply voltage Vdd is set at 1.8 V, for example. In this case, the power-supply voltage Vdd is provided from the outside of the semiconductor memory device 70. Alternatively, a power-supply voltage Vdd generated within the semiconductor memory device 70 may be used.

The booster circuit 3 receives the power-supply voltage Vdd as an input voltage. When the control signal Secp2 is in an enabling state, the booster circuit 3 generates a boosted voltage Vpp obtained by booster the power-supply voltage Vdd. When the control signal Secp2 is in a disabling state, the booster circuit 3 stops operating.

The booster circuit 4 receives the power-supply voltage Vdd as an input voltage. When the control signal Secp3 is in an enabling state, the booster circuit 4 generates a negative boosted voltage Vera obtained by booster the power-supply voltage Vdd. When the control signal Secp3 is in a disabling state, the booster circuit 4 stops operating.

Each of the booster circuits 2 to 4 is a charge pump circuit. The boosted voltage Vpg, which is outputted from the booster circuit 2 and is inputted into the memory cell unit 1, is used for writing and reading operations, for example. The boosted voltage Vpp, which is outputted from the booster circuit 3 and is inputted into the memory cell unit 1, is used for writing and erasing operations, for example. The boosted voltage Vera, which is outputted from the booster circuit 4 and is inputted into the memory cell unit 1, is used for an erasing operation, for example.

The boosted voltage Vpg outputted from the booster circuit 2 is sent to a switch SW1. The boosted voltage Vpp outputted from the booster circuit 3 is sent to a switch SW2. The boosted voltage Vpg is set at 5 V, for example. The boosted voltage Vpp is set at 10 V, for example. The boosted voltage Vera is set at −7 V, for example.

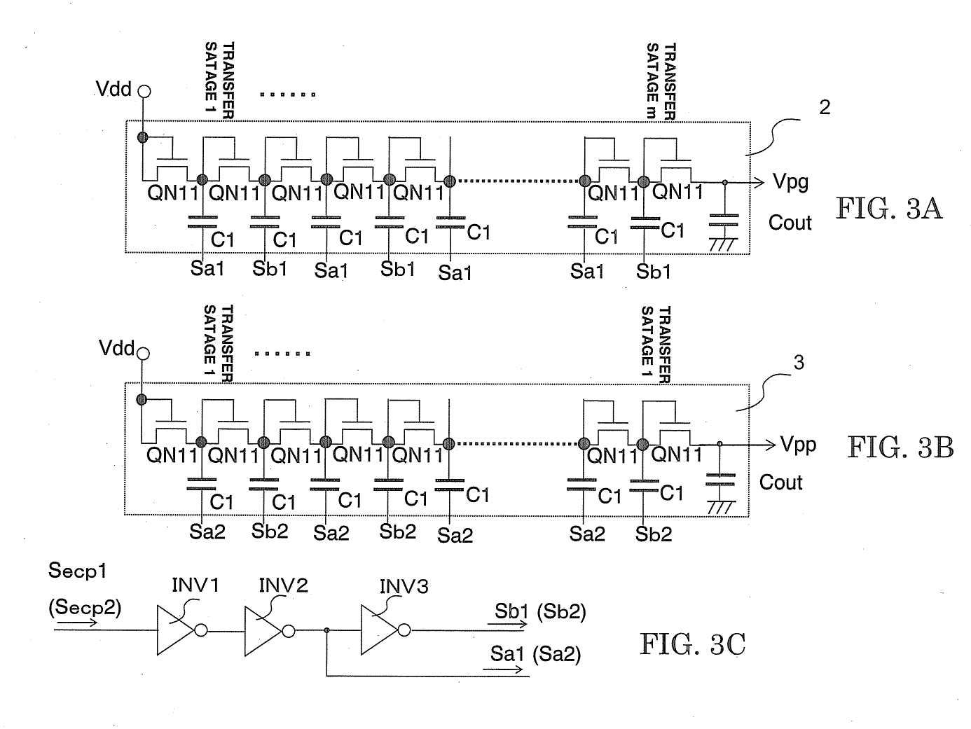

As illustrated in FIGS. 3A and 3B, each of the booster circuits 2, 3 is a Dickson charge pump circuit. In each of the booster circuits 2, 3, each transfer stage is constituted by an Nch MOS transistor QN11 and a capacitor C1, and a capacitor Cout is provided at an output side. FIG. 3C illustrates a circuit for generating a voltage to be provided to the circuits shown in FIG. 3A or 3B. Two circuits having the same configuration as illustrated in FIG. 3C are arranged in the booster circuits 2, 3. In the booster circuits 2, 3, the control signals Secp1, Secp2 pass through invertors INV1, INV2 to become control signals Sa1, Sa2, respectively. The control signals Sa1, Sa2 are provided to the capacitors C1 arranged at odd number stages of the booster circuits 2, 3, respectively. In the booster circuits 2, 3, the control signals Secp1, Secp2 pass through invertors INV1, INV2, and INV3 to become control signals Sb1, Sb2 (reverse signals of the control signal Secp1), respectively. The control signals Sb1, Sb are provided to the capacitors C1 arranged at even number stages of the booster circuits 2, 3, respectively.

The boosted voltage Vpg outputted from the booster circuit 2 and the boosted voltage Vpp outputted from the booster circuit 3 are expressed by the following equations. In the equations below, “n” and “m” are integer and satisfy n>m. “Vthn” is a threshold voltage of the Nch MOS transistors QN11.

Vpg=(m+1)×(Vdd−Vthn) (1 )

Vpp=(n+1)×(Vdd−Vthn) (2)

A current Ish1 flowing in the booster circuit 2 and a current Ish2 flowing in the booster circuit 3 are represented by the following equations. In the equations below, Iocp1 denotes an output current of the booster circuit 2, Iocp2 denotes an output current of the booster circuit 3, Ycp1 denotes a booster efficiency of the booster circuit 2, and Ycp2 denotes a booster efficiency of the booster circuit 3.

Ish1=(Vpg×Iocp1×Ycp1)/Vdd (3)

Ish2=(Vpp×Iocp2×Ycp2)/Vdd (4)

In general, the output current of the booster circuit is proportional to the number of transfer stages, and the booster efficiency of the booster circuit is inversely proportional to the number of transfer stages. Therefore, the current in each of the charge pump circuits of the booster circuits 2, 3 increases according to the number of transfer stages. The relationship between the current Ish1 of the booster circuit 2 and the current Ish2 of the booster circuit 3 are derived from the equations (1) to (4) and are represented by the following equation. In the equations below, A is a constant number.

Ish/lsh2=A×{(m+1)/(n+1)} (5)

The booster circuit 4 as illustrated in FIG. 1 is a circuit equivalent to the booster circuits 2, 3. In FIG. 1, the regulator control circuit 7 receives an operation mode control signal Sdm outputted from the mode control circuit 6. The regulator control circuit 7 generates switching signals Ssw1, Ssw2, a regulator control signal Srs1, and an output voltage control signal Srs2 based on the operation mode control signal Sdm.

The switch SW1 receives the boosted voltage Vpg. When the switching signal Ssw1 is in an enabling state, the switch SW1 is turned on so as to provide the boosted voltage Vpg to the regulator 5. When the switching signal Ssw1 is in a disabling state, the switch SW1 is turned off so as to shut off the boosted voltage Vpg.

The switch SW2 receives the boosted voltage Vpp. When the switching signal Ssw2 is in an enabling state, the switch SW2 is turned on so as to provide the boosted voltage Vpp to the regulator 5. When the switching signal Ssw2 is in a disabling state, the switch SW2 is turned off so as to shut off the boosted voltage Vpp.

The switching signals Ssw1 and Ssw2 do not overlap with each other in an enabling state. When the switch SW1 is turned on and the switch SW2 is turned off, the boosted voltage Vpg is supplied to the regulator 5 as the power-supply voltage. When the switch SW2 is turned on and the switch SW1 is turned off, the boosted voltage Vpp is supplied to the regulator 5 as the power-supply voltage.

The regulator 5 receives the regulator control signal Srs1 and the output voltage control signal Srs2, and receives the boosted voltage Vpg or the boosted voltage Vpp as the power-supply voltage. The regulator 5 drops the boosted voltage based, on the regulator control signal Srs1 and the output voltage control signal Srs2. Further, the regulator 5 generates a plurality of dropped voltages Vreg having different values which are lower than the boosted voltages, and provides the dropped voltages Vreg to a selected word line (WL) of the memory unit 11, for example. The plurality of dropped voltages Vreg are used for operations such as rewriting, writing, step-up writing, writing verification, erasing verification, and reading.

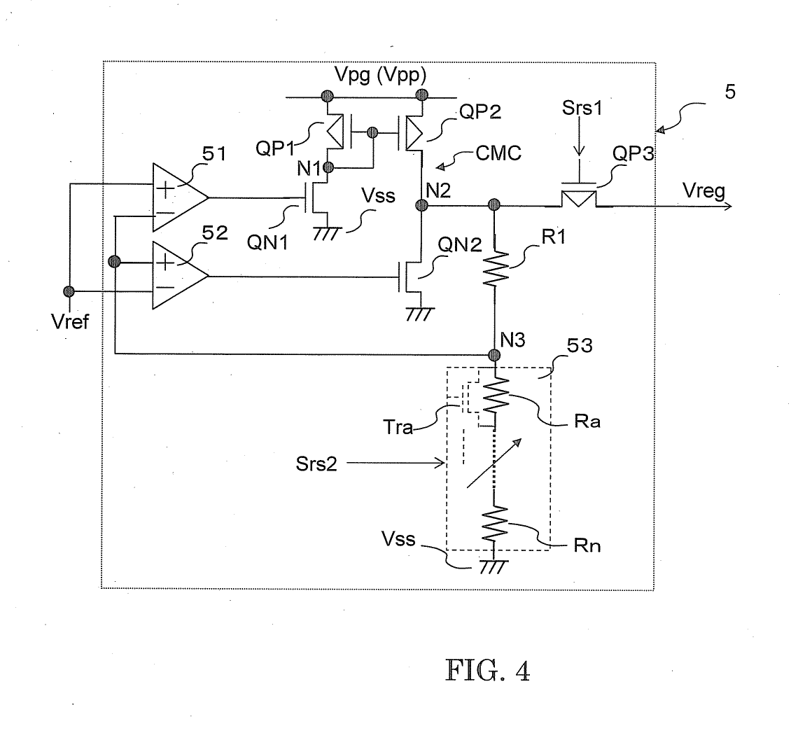

As illustrated in FIG. 4, the regulator 5 is a series regulator. The regulator 5 includes comparators 51, 52, a variable resistor unit 53, Nch MOS transistors QN1, QN2, Pch MOS transistors QP1, QP3, a resistor R1, and a variable resistor unit 53.

The Pch MOS transistor QP1 includes a source, a drain, and a gate. The source receives the boosted voltage Vpg or the boosted voltage Vpp. The gate is connected to the drain, and the drain is connected to a node N1. The Pch MOS transistor QP2 includes a source, a drain, and a gate. The source receives the boosted voltage Vpg or the boosted voltage Vpp. The gate is connected to the gate of the MOS transistor QP1. The drain is connected to a node N2. The Pch MOS transistors QP1 and QP2 as well as the Nch MOS transistors QN1, QN2 constitute a current mirror circuit CMC.

The Nch MOS transistor QN1 includes a source, a drain, and a gate, which is an input terminal of the current mirror circuit CMC. The drain is connected to a node N1. The gate receives the output signal of the comparator 51. The source is set at a ground potential Vss. The Nch MOS transistor QN2 includes a source, a drain, and a gate which is an input terminal of the current mirror circuit CMC. The drain is connected to the node N2. The gate receives the output signal of the comparator 52. The source is set at the ground potential Vss.

One end of the resistor R1 is connected to the node N2. The other end of the resistor R1 is connected to the node N3. The variable resistor unit 53 is arranged between the node N3 and the ground potential Vss, and includes n resistors Ra, . . . , Rn which are cascade-connected. Based on the output voltage control signal Srs2, the variable resistor unit 53 changes a resistance value. In more detail, switches Tra made of MOS transistors connected in parallel with the resistors respectively are made on or off by the output voltage control signal Srs2 so that the resistors Ra, . . . , Rn are selected and the resistance value is changed. As a result, the voltage of the node N3 is changed by the output voltage control signal Srs2, and the changed feedback voltage is given to the comparators 51, 52.

A plus (+) port provided at the input side of the comparator 51 receives a reference voltage Vref. A minus (−) port provided at the input side of the comparator 51 receives the feedback voltage of the node N3. The comparator 51 outputs the compared and amplified signal to the gate of the Nch MOS transistor QN1.

A plus (+) port provided at the input side of the comparator 52 receives the feedback voltage of the node N3. A minus (−) port provided at the input side of the comparator 52 receives the reference voltage Vref. The comparator 52 outputs the compared and amplified signal to the gate of the Nch MOS transistor QN2.

The Pch MOS transistor QP3 includes a source, a drain, and a gate. The source is connected to the node N2. The gate receives the regulator control signal Srs1. When the regulator control signal Srs1 is in an enabling state, the Pch MOS transistor QP3 is turned on. At this time, the drain outputs a plurality of different dropped voltages Vreg generated based on the output voltage control signal Srs2. When the regulator control signal Srs1 is in a disabling state, the Pch MOS transistor QP3 is turned off. In the state, the regulator 5 does not output any dropped voltage Vreg.

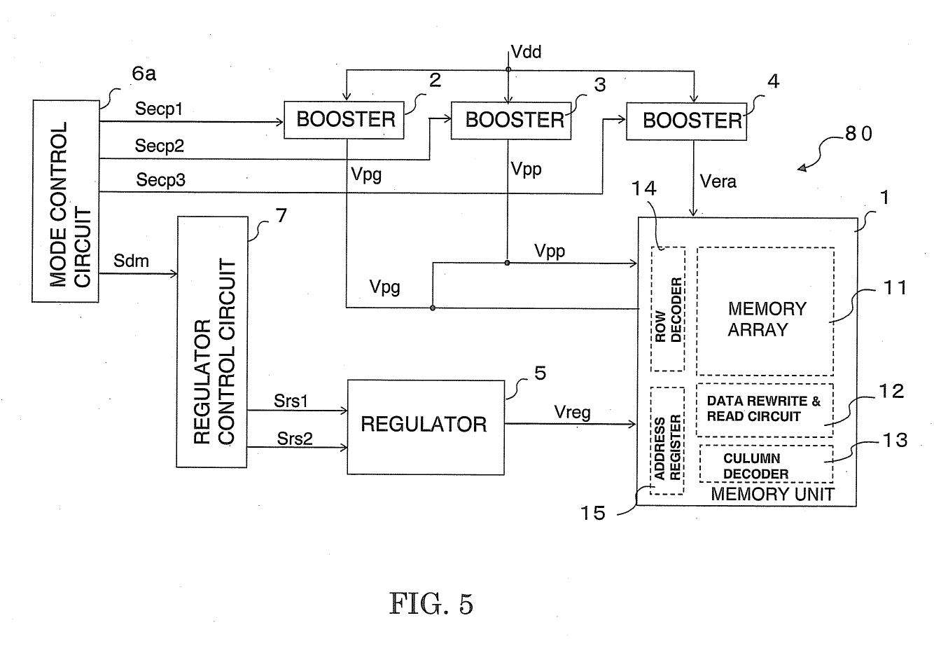

FIG. 5 illustrates a semiconductor memory device 80 according to the first comparative example. The semiconductor memory device 80 includes a memory unit 1, booster circuits 2 to 4, a regulator 5a, a mode control circuit 6a, and a regulator control circuit 7a. Similarly to the first embodiment as described above, the semiconductor memory device 80 is a NOR flash memory, and each memory cell transistor of the semiconductor memory device 80 can store information of four values (2 bits).

The mode control circuit 6 generates control signals Secp1a, Secp2a and Secp3 for controlling the booster circuits 2 to 4 respectively, and generates an operation mode control signal Sdma. When the control signals Secp1a, Secp2a and Secp3 are in an enabling state, the booster circuits 2 to 4 operate respectively. When the control signal Secp1a, the control signal Secp2a, and the control signal Secp3 are in a disabling state, the booster circuits 2 to 4 are turned off respectively.

The booster circuit 2 receives, as an input voltage, a power-supply voltage Vdd provided from the outside of the semiconductor memory device 80. When the control signal Secp1a is in an enabling state, the booster circuit 2 generates a boosted voltage Vpg obtained by booster the power-supply voltage Vdd. When the control signal Secp1a is in a disabling state, the booster circuit 2 stops operating.

The booster circuit 3 receives the power-supply voltage Vdd as an input voltage. When the control signal Secp2 is in an enabling state, the booster circuit 3 generates a boosted voltage Vpp obtained by booster the power-supply voltage Vdd, and outputs the boosted voltage Vpp to the memory unit 1 and the regulator 5a. When the control signal Secp2a is in a disabling state, the booster circuit 3 stops operating.

The regulator control circuit 7a receives the operation mode control signal Sdma outputted from the mode control circuit 6a. The regulator control circuit 7a generates a regulator control signal Srs1a, and an output voltage control signal Srs2a based on the operation mode control signal Sdma.

The regulator 5a receives the regulator control signal Srs1a and the output voltage control signal Srs2a, and receives the boosted voltage Vpp as the power-supply voltage. The regulator 5a drops the boosted voltage boosted by the booster circuit 3 based on the regulator control signal Srs1a and the output voltage control signal Srs2a. As a result, the regulator 5a generates a plurality of dropped voltages Vreg which is lower than the boosted voltages having different values, and provides the dropped voltages Vreg to a selected word line (WL) of the memory cell array 11, for example. The regulator 5a is a series regulator, and has a circuit configuration including a variable resistor unit similar to the regulator 5 as illustrated in FIG. 4.

In the semiconductor memory device 80 according to the first comparative example, the boosted voltage Vpp is used not only for writing and erasing operations for the memory unit 1 but also for the power-supply voltage to be provided to the regulator 5a. In contrast, in the semiconductor memory device 70 according to the above embodiment, the boosted voltage Vpp and the boosted voltage Vpg are selectively used.

In the first comparative example, the booster circuit 3 consuming a largest power is used more frequently than in the semiconductor memory device 70 of the present embodiment. Therefore, in the comparative example, the average power consumption is larger than that of the semiconductor memory device 70 of the present embodiment. The average power consumption is an average value of the powers consumed in the entire semiconductor memory device.

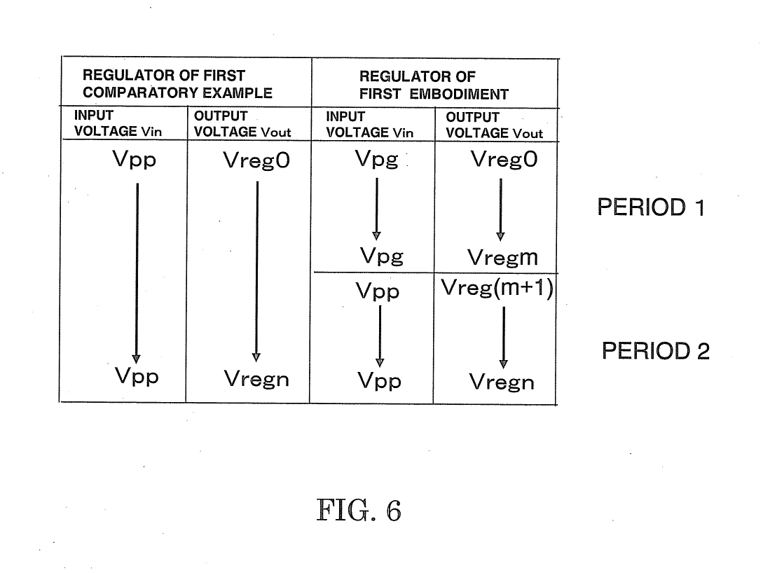

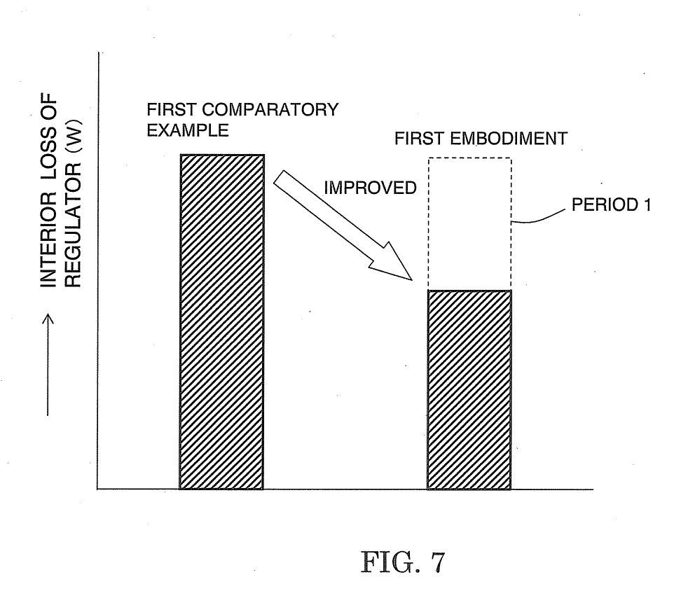

The internal losses occurring in the regulators of the present embodiment and the first comparative example will be described with reference to FIGS. 6 and 7. FIG. 6 illustrates relationships between input voltages and output voltages of the regulators of the present embodiment and the first comparative example. FIG. 7 illustrates internal losses of the regulator according to the present embodiment and the first comparative example.

As illustrated in FIG. 6, the regulator 5a according to the first comparative example receives only the boosted voltage Vpp as the power-supply voltage, and generates a plurality of dropped voltages Vreg0, . . . , Vregn having different values by dropping the boosted voltage Vpp.

In contrast, the regulator 5 of the present embodiment is as follows. In a period 1 when the output voltage is allowed to be relatively low, the regulator 5 receives, as the power-supply voltage, the boosted voltage Vpg lower than the boosted voltage Vpp, and generates a plurality of dropped voltages Vreg0, . . . , Vregm having different values by dropping the boosted voltage Vpg. In a period 1 when the output voltage needs to be relatively high, the regulator 5 receives, as the power-supply voltage, the boosted voltage Vpp higher than the boosted voltage Vpb, and generates a plurality of dropped voltages Vreg(m+1), . . . , Vregn having different values higher than the boosted voltage Vpg by dropping the boosted voltage Vpp. In the period 2, the input voltage Vin of the regulator 5 and the input voltage Vin of the regulator 5a are the same, i.e., the boosted voltage Vpp.

In general, a relationship between an internal loss Ross, an input voltage Vin, an output voltage Vout, an output current Tout of the regulator is represented by the following equation.

Ross=(Vin−Vout)×Iout (6)

The internal loss Ross is discharged as heat, for example, and increases the temperature of the semiconductor memory device. The larger the internal loss Ross is, the higher the temperature is.

In the period 1, an internal loss RossA of the regulator 5a of the first comparative example and an internal loss RossB of the regulator 5 of the present embodiment are represented by the following equation. Vregi is the dropped voltage in the period 1. In this case, the output current of the regulator 5a and the output current of the regulator 5 are the same value.

RossA=(Vpp−Vregi)×Iout (7)

RossB=(Vpg−Vregi)×Iout (8)

The boosted voltage Vpp is larger than the boosted voltage Vpg. As illustrated in FIG. 7, the internal loss RossA of the regulator 5a of the first comparative example is larger than the internal loss RossB of the regulator 5 of the present embodiment. Therefore, the internal loss of the regulator of the first comparative example occuring in the period 1 is improved in the semiconductor memory device 70 according to the present embodiment. The amount of improvement ΔRoss of the internal loss of the regulator is represented by the following equation.

Gross=(Vpp−Vpg)×Iout (9)

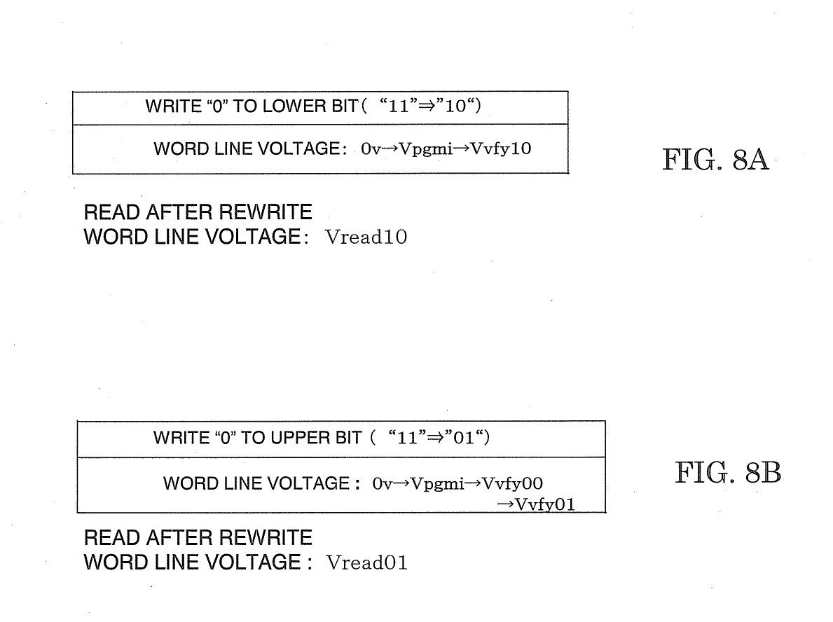

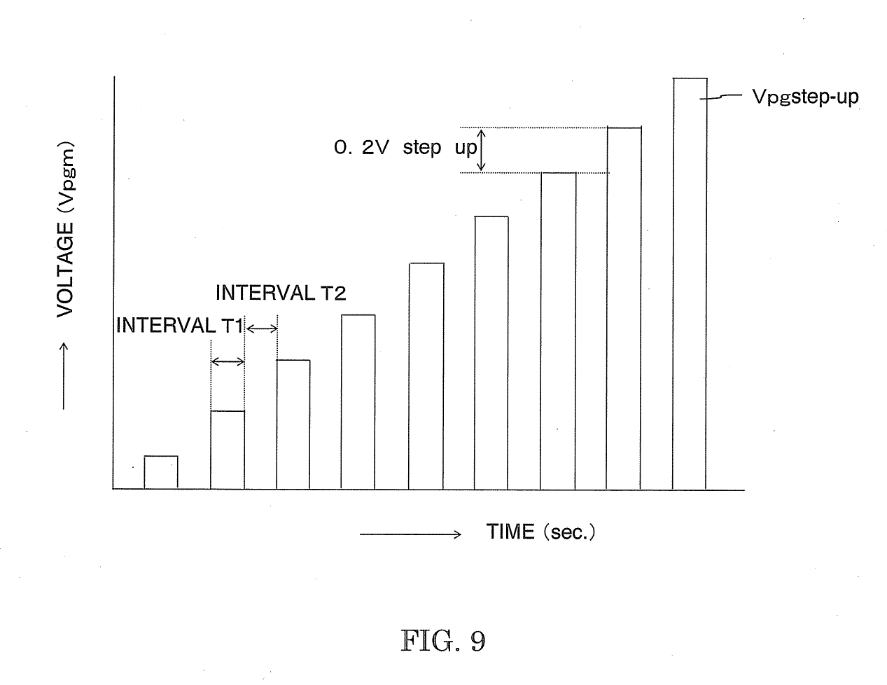

Operation of the semiconductor memory device using a plurality of dropped voltages generated by the regulator 5 of the present embodiment will be described with reference to FIGS. 8A, 8B, and 9.

The plurality of dropped voltages Vreg0, . . . , Vregm, Vreg(m+1), Vregn generated by the regulator 5, as illustrated in FIG. 6, are provided to a selected word line (WL), for example. The dropped voltages are used to perform operations such as rewriting, writing, step-up writing, writing verification, erasing verification, and reading. As an example, rewriting of data, reading of data, and step-up writing will be described below. In order to simplify explanation, only the case of setting a voltage applied to a selected word line (WL) will be described. Description regarding settings voltages applied to a bit line (BL), an unselected word line (WL), a source line (SL), and a well (Well) will be omitted.

FIGS. 8A and 8B illustrate examples of data rewriting and data reading operation performed according to the present embodiment. FIG. 8A illustrates rewriting and reading of a lower bit. FIG. 8B illustrates rewriting and reading of an upper bit.

In the example of FIG. 8A, “0” is written to a lower bit so that information representing “11” is changed to “10”. More specifically, a selected word line (WL) is set at 0 (zero) V. Then, the selected word line (WL) is set at a writing voltage Vpgmi. Subsequently, the selected word line (WL) is set at the writing verification voltage Vvfy10 so that data are rewritten. When the data are read after the rewriting, the selected word line (WL) is set at the reading voltage Vread10 so that the data stored in a memory cell transistor are read.

In the example of FIG. 8B, “0” is written to a higher bit so that information representing “11” is changed to “01”. More specifically, a selected word line (WL) is set at 0 (zero) V. Then, the selected word line (WL) is set at the writing voltage Vpgmi. Subsequently, the selected word line (WL) is set at the writing verification voltage Vvfy00. Further, the selected word line (WL) is set at the writing verification voltage Vvfy01 so that data are rewritten. When the data are read after the rewriting, the selected word line (WL) is set at the reading voltage Vread01 so that the data stored in the memory cell transistor of the memory cell array 11 is read.

FIG. 9 illustrates change of a writing voltage during step-up writing according to the present embodiment. As illustrated in FIG. 9, the step-up writing is performed using the plurality of dropped voltages Vreg generated by the regulator 5. More specifically, a selected word line (WL) is set at a writing voltage Vpgstep-up, i.e., a step-up writing voltage successively boosted from 0 V. The writing voltage Vpgstep-up includes a pulse ON period T1, a pulse interval T2, and a step-up amount 0.2 V. This step-up writing voltage improves the accuracy of writing to a memory cell transistor. [0058]

As described above, the semiconductor memory device according to the embodiment is provided with the switch SW1 and the switch SW2. The switch SW1 receives the boosted voltage Vpg. The switch SW1 is turned on based on the switching signal Ssw1, in an enabling state, so that the boosted voltage Vpg can be provided to the regulator 5. The switch SW2 receives the boosted voltage Vpp. The switch SW2 is turned on based on the switching signal Ssw2, in an enabling state, so that the boosted voltage Vpp can be provided to the regulator 5. Thus, the regulator 5 receives, as a power-supply voltage, one of the boosted voltage Vpg and the boosted voltage Vpp via the switch SW1 or the switch SW2. The regulator 5 drops the boosted voltage, generates a plurality of dropped voltages Vreg having different values, and outputs the dropped voltages Vreg to the memory unit 1.

The regulator 5 uses the boosted voltage Vpp and the boosted voltage Vpg selectively. This can reduce the frequency of using the booster circuit 3 which consumes a largest current, and can greatly reduce the average power consumption in the semiconductor memory device 70. In addition, the difference between the input and the output voltages of the regulator 5 can be reduced. Therefore, the internal loss of the regulator 5 can be greatly improved.

In the embodiment, the booster circuits 2 to 4 are provided with Dickson charge pump circuits respectively. However, the embodiment is not limited to using the Dickson charge pump circuits. Alternatively, the embodiment may employ a complementary charge pump circuit or a boost converter circuit, which has a higher efficiency than a Dickson charge pump circuit. The switches SW1, SW2 may use SPST (single pole single throw) switches. Alternatively, the switches SW1, SW2 may use DPST (double pole single throw) switches.

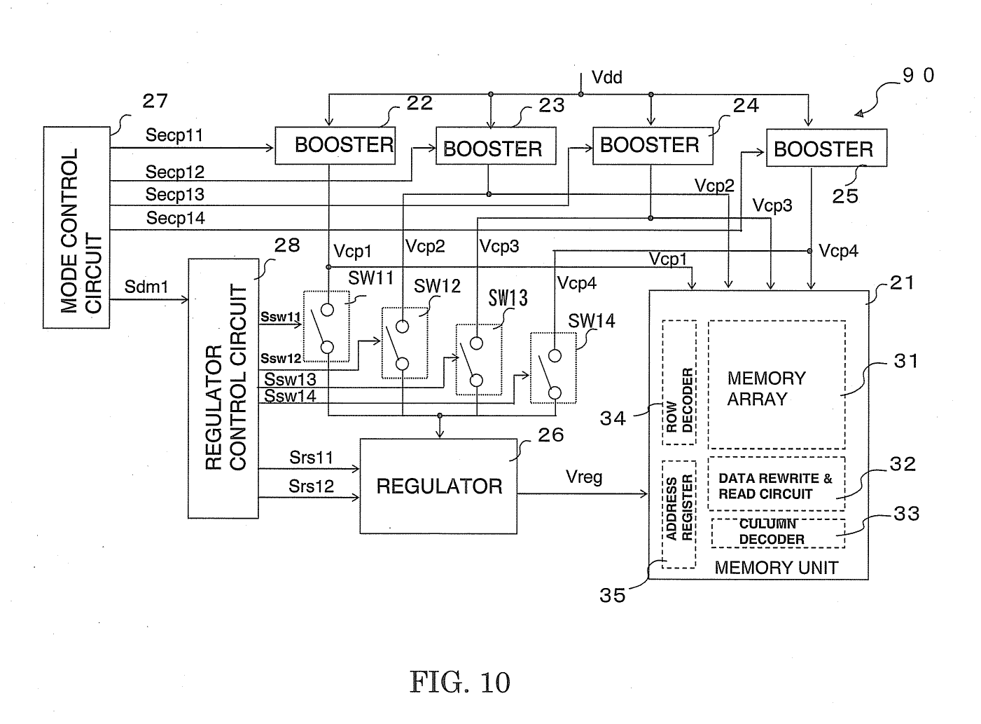

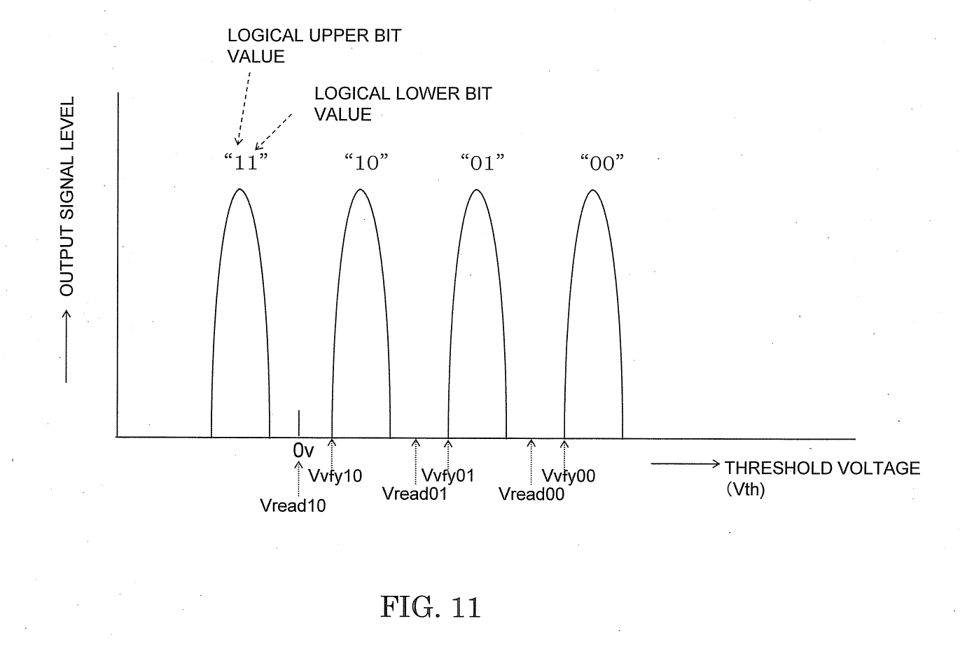

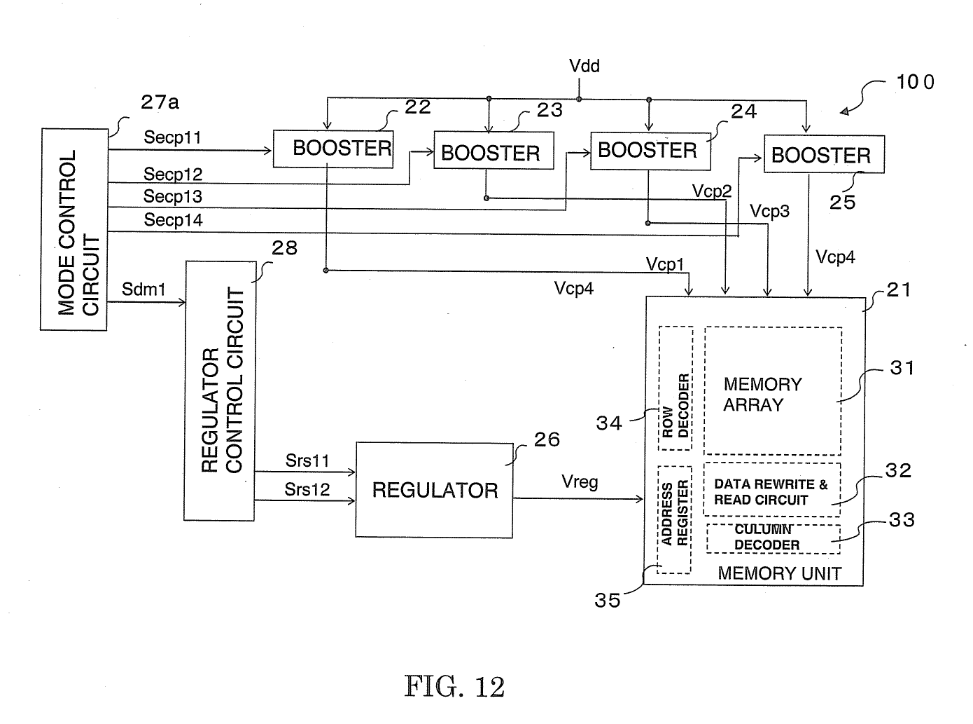

A semiconductor memory device according to the second embodiment will be described with reference to drawings. FIG. 10 is a block diagram illustrating a schematic configuration of a semiconductor memory device. FIG. 11 illustrates a relationship between threshold voltages, output signal levels and data of a memory cell transistor. FIG. 12 is a block diagram illustrating a schematic configuration of a semiconductor memory device according to a second comparative example. In the present embodiment, boosted voltages having different values outputted from four booster circuits are selectively inputted to a regulator via switches, and the regulator generates a plurality of dropped voltages and provides the dropped voltages to a memory unit.

As illustrated in FIG. 10, a semiconductor memory device 90 is provided with a memory unit 21, booster circuits 22 to 25, a regulator 26, a mode control circuit 27, a regulator control circuit 28, and switches SW1 to SW14. The semiconductor memory device 90 is a NAND flash memory, each memory cell transistor of which can store information of four values (2 bits). The switches SW11 to SW14 are SPST switches. Alternatively, 4PST switches may be used.

The memory unit 21 is provided with a memory cell array 31, an address register 35, a row decoder 34, a column decoder 33, and a data rewriting and reading circuit 32. In the memory cell array 31, memory cells for storing data are arranged in a matrix. The address register 35 designates an address of a memory cell. The row decoder 34 is connected to word lines (WL) of the memory cell array 31. The column decoder 33 is connected to bit lines (BL) of the memory cell array 31. The data rewriting and reading circuit 32 rewrites and reads data.

FIG. 11 illustrates a relationship between threshold voltages, output signal levels and data of a memory cell transistor provided in the memory cell array 31 according to the second embodiment. The memory cell transistor provided in the memory cell array 31 stores information of four values (2 bits), i.e., “11”, “10”, “01”, and “00” as illustrated in FIG. 11.

The information “11” is distributed in a threshold voltage (Vth) range less than 0 (zero). For example, the information “11” is distributed in a threshold voltage range equal to or more than −2.0 V. The information “10” is distributed within a threshold voltage (Vth) range between a reading voltage Vreadl0 and a reading voltage Vread01. The threshold voltage (Vth) is equal to or more than a writing verification voltage Vvfy10. The information “01” is distributed within a threshold voltage (Vth) range between the reading voltage Vread01 and a reading voltage Vread00. The threshold voltage (Vth) is equal to or more than a writing verification voltage Vvfy01. The information “00” is distributed in a threshold voltage (Vth) range being more than the reading voltage Vread00. The threshold voltage (Vth) is equal to or more than a writing verification voltage Vvfy00.

The reading voltage Vread10 is set at 0 (zero) V, for example. The reading voltage Vread01 is set at 1.0 V, for example. The reading voltage Vread00 is set at 2.0 V, for example. The writing verification voltage Vvfy10 is set at 0.4 V, for example. The writing verification voltage Vvfy01 is set at 1.4 V, for example. The writing verification voltage Vvfy00 is set at 2.4 V, for example.

In FIG. 10, the mode control circuit 27 generates control signals Secp11 to Secp14 for controlling the booster circuits 22 to 25 respectively, and generates an operation mode control signal Sdm1. When the control signals Secp11 to Secp14 are in an enabling state, the booster circuits 22 to 25 operate respectively. When the control signals Secp11 to Secp14 are in a disabling state, the booster circuits 22 to 25 are turned off respectively.

The booster circuit 22 receives, as an input voltage, a power-supply voltage Vdd provided from the outside of the semiconductor memory device 90. When the control signal Secp11 is in an enabling state, the booster circuit 22 generates a boosted voltage Vcp1 obtained by booster the power-supply voltage Vdd. When the control signal Secp11 is in a disabling state, the booster circuit 22 stops operating. The power-supply voltage Vdd is set at a value in range from 1.8 V to 3.3 V, for example. The power-supply voltage Vdd is set at 1.8 V, for example. In this case, the power-supply voltage Vdd is provided from the outside of the semiconductor memory device 90. Alternatively, a power-supply voltage Vdd generated within the semiconductor memory device 90 may be used.

The booster circuit 23 receives the power-supply voltage Vdd as an input voltage. When the control signal Secp11 is in an enabling state, the booster circuit 23 generates a boosted voltage Vcp2 obtained by booster the power-supply voltage Vdd. When the control signal Secp12 is in a disabling state, the booster circuit 23 stops operating.

The booster circuit 24 receives the power-supply voltage Vdd as an input voltage. When the control signal Secp13 is in an enabling state, the booster circuit 24 generates a boosted voltage Vcp3 obtained by booster the power-supply voltage Vdd. When the control signal Secp13 is in a disabling state, the booster circuit 24 stops operating.

The booster circuit 25 receives the power-supply voltage Vdd as an input voltage. When the control signal Secp14 is in an enabling state, the booster circuit 25 generates a boosted voltage Vcp4 obtained by booster the power-supply voltage Vdd. When the control signal Secp14 is in a disabling state, the booster circuit 25 stops operating.

Each of the booster circuits 22 to 25 is a Dickson charge pump circuit having the same configuration as the circuits described with reference to FIGS. 3A to 3C. The boosted voltage Vcp1, which is outputted from the booster circuit 22 and inputted into the memory cell unit 21, is used to apply a voltage to a selected word line (WL) for writing data to a memory cell. The boosted voltage Vcp1 is set at 20 V, for example. The boosted voltage Vcp2, which is outputted from the booster circuit 23 and is inputted into the memory cell unit 21, is used for applying a voltage to an unselected word line (WL). For example, the boosted voltage Vcp2 is set at 12 V. The boosted voltage Vcp3, which is outputted from the booster circuit 24 and inputted into the memory cell unit 21, is used to perform a reading operation for reading data from a memory cell. The boosted voltage Vcp3 is set at 8 V, for example. The boosted voltage Vcp4, which is outputted from the booster circuit 25 and inputted into the memory cell unit 21, is used for a verification operation. The boosted voltage Vcp4 is set at 4 V, for example.

In FIG. 10, two booster circuits is omitted to be illustrated. One of the booster circuits is used to set a potential of a control signal to control selection transistors for selecting bit lines (BL) and source lines (SL) which are provided in the memory cell array 31 of the NAND flash memory. The other of the booster circuits is used to erase data stored in a memory cell transistor of the memory cell array 31.

The boosted voltage Vcp1 outputted from the booster circuit 22 is provided to the switch SW11. The boosted voltage Vcp2 outputted from the booster circuit 23 is provided to the switch SW12. The boosted voltage Vcp3 outputted from the booster circuit 24 is provided to the switch SW13. The boosted voltage Vcp4 outputted from the booster circuit 25 is provided to the switch SW14. The booster circuits 22 to 25 have different numbers of transfer stages. The booster circuit 22 has a largest number of transfer stages.

The regulator control circuit 28 receives the operation mode control signal Sdm1 outputted from the mode control circuit 27. The regulator control circuit 28 generates switching signals Ssw11 to Ssw 14, a regulator control signal Srs11, and an output voltage control signal Srs12, based on an operation mode control signal Sdm1.

When the switching signal Ssw11 is in an enabling state, the switch SW11 is turned on so as to pass the boosted voltage Vcp1. When the switching signal Ssw11 is in a disabling state, the switch SW11 is turned off so as to shut off the boosted voltage Vcp1.

When the switching signal Ssw12 is in an enabling state, the switch SW12 is turned on so as to pass the boosted voltage Vcp2. When the switching signal Ssw12 is in a disabling state, the switch SW12 is turned off so as to shut off the boosted voltage Vcp2.

When the switching signal Ssw13 is in an enabling state, the switch SW13 is turned on so as to pass the boosted voltage Vcp3. When the switching signal Ssw13 is in a disabling state, the switch SW13 is turned off so as to shut off the boosted voltage Vcp3.

When the switching signal Ssw14 is in an enabling state, the switch SW14 is turned on so as to pass the boosted voltage Vcp4. When the switching signal Ssw14 is in a disabling state, the switch SW14 is turned off so as to shut off the boosted voltage Vcp4.

The switching signals Ssw1 to Ssw4, in an enabling state, do not overlap with each other. When the switch SW11 is turned on, the switches SW12 to SW14 are turned off, and the boosted voltage Vcp1 is supplied to the regulator 26 as the power-supply voltage. When the switch SW12 is turned on, the switch SW11, the switch SW13, and the switch SW14 are turned off, and the boosted voltage Vcp2 is supplied to the regulator 26 as the power-supply voltage. When the switch SW13 is turned on, the switch SW11, the switch SW12, and the switch SW14 are turned off, and the boosted voltage Vcp3 is supplied to the regulator 26 as the power-supply voltage. When the switch SW14 is turned on, the switches SW11 to SW13 are turned off, and the boosted voltage Vcp4 is supplied to the regulator 26 as the power-supply voltage.

The regulator 26 is a series regulator having a variable resistor unit, which has the same configuration as the regulator circuit 5 of the first embodiment described with reference to FIG. 4. The regulator 26 receives a regulator control signal Srs11 and an output voltage control signal Srs12, and provides one of the boosted voltages Vcp1 to Vcp4 as the power-supply voltage. The regulator 26 drops the boosted voltage based on the regulator control signal Srs11 and the output voltage control signal Srs12. The regulator 26 generates a plurality of dropped voltages Vreg which are lower than the boosted voltages having different values. Then, the regulator 26 provides the dropped voltages Vreg to a selected word line (WL) of the memory unit 21, for example.

The dropped voltages Vreg provided by the regulator 26 are used to perform operations such as rewriting, writing, step-up writing, writing verification, erasing verification, and reading.

FIG. 12 illustrates a semiconductor memory device 100 according to the second comparative example. The semiconductor memory device 100 according to the second comparative example is provided with a memory unit 21, booster circuits 22 to 25, a regulator 26a, a mode control circuit 27a, and a regulator control circuit 28a. The semiconductor memory device 100 is a NAND flash memory, each memory cell transistor of which can store information of four values (2 bits). In the description below, only differences from the semiconductor memory device 90 of the second embodiment as illustrated in FIG. 10 will be described.

The mode control circuit 27a generates control signals Secp11a to Secp14a for controlling the booster circuits 22 to 25 respectively, and generates an operation mode control signal Sdm1a. When the control signals Secp11a to Secp14a are in an enabling state, the booster circuits 22 to 25 operate respectively. When the control signals Secp11a to Secp14a are in a disabling state, the booster circuits 22 to 25 are turned off respectively.

The booster circuit 22 receives, as an input voltage, a power-supply voltage Vdd provided from the outside of the semiconductor memory device 100. When the control signal Secp11a is in an enabling state, the booster circuit 22 generates a boosted voltage Vcp1 obtained by booster the power-supply voltage Vdd, and outputs the boosted voltage Vcp1 to the memory unit 21 and the regulator 26a. When the control signal Secp11a is in a disabling state, the booster circuit 22 stops operating.

The booster circuit 23 receives the power-supply voltage Vdd as an input voltage. When the control signal Secp12a is in an enabling state, the booster circuit 23 generates a boosted voltage Vcp2 obtained by booster the power-supply voltage Vdd, and outputs the boosted voltage Vcp2 to the memory unit 21. When the control signal Secp12a is in a disabling state, the booster circuit 23 stops operating.

The booster circuit 24 receives the power-supply voltage Vdd as an input voltage. When the control signal Secp13a is in an enabling state, the booster circuit 24 generates a boosted voltage Vcp3 obtained by booster the power-supply voltage Vdd, and outputs the boosted voltage Vcp3 to the memory unit 21. When the control signal Secp13a is in a disabling state, the booster circuit 24 stops operating.

The booster circuit 25 receives the power-supply voltage Vdd as an input voltage. When the control signal Secp14a is in an enabling state, the booster circuit 25 generates a boosted voltage Vcp4 obtained by booster the power-supply voltage Vdd, and outputs the boosted voltage Vcp4 to the memory unit 21. When the control signal Secp14a is in a disabling state, the booster circuit 25 stops operating. The booster circuit 22 consumes a largest power among the booster circuits 22 to 25.

The regulator 26a is a series regulator provided with a variable resistor unit. The regulator 26a has a circuit configuration similar to the regulator 26 of the second embodiment. The regulator control circuit 28a receives the operation mode control signal Sdm1a outputted from the mode control circuit 27a. The regulator control circuit 28a generates a regulator control signal Srs11a and an output voltage control signal Srs12a based on the operation mode control signal Sdm1a.

The regulator 26a receives the regulator control signal Srs11a and the output voltage control signal Srs12a, and receives the boosted voltage Vcp1 as the power-supply voltage. Similarly to the second embodiment, the regulator 26a drops the boosted voltage Vcpl based on the regulator control signal Srs11a and the output voltage control signal Srs12a. The regulator 5a drops the voltage to generate a plurality of dropped voltages Vreg having different values which are lower than the boosted voltage, and provides the dropped voltages Vreg to a selected word line (WL) of the memory unit 21, for example.

In contrast, in the second comparative example, the boosted voltage Vcp1 is always used as the power-supply voltage of the regulator 26a. On the other hand, in the second embodiment, one of the boosted voltages Vcp1 to Vcp4 is selectively used as the power-supply voltage of the regulator 26a.

Therefore, in the second comparative example, the booster circuit 22 which consumes a largest power is used more frequently than in the semiconductor memory device 90 of the second embodiment. Accordingly, in the second comparative example, the average power consumption is larger than that of the second embodiment.

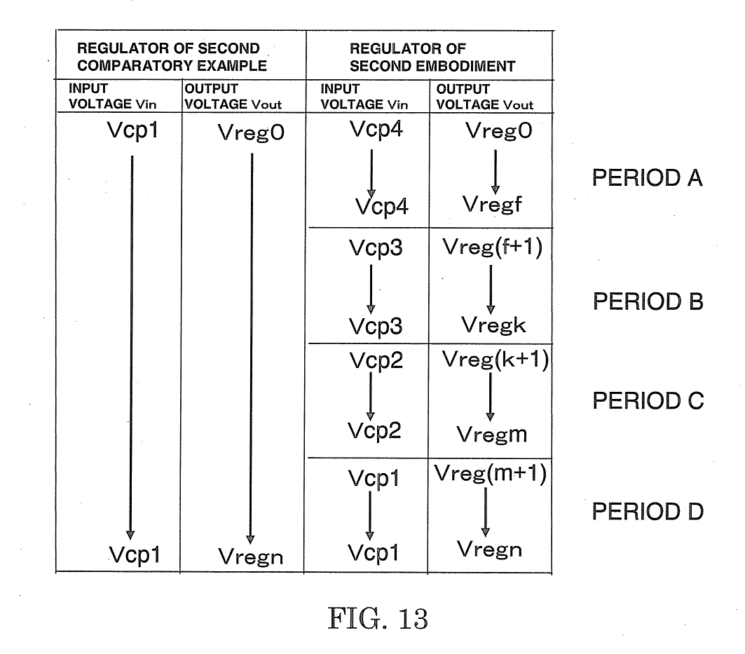

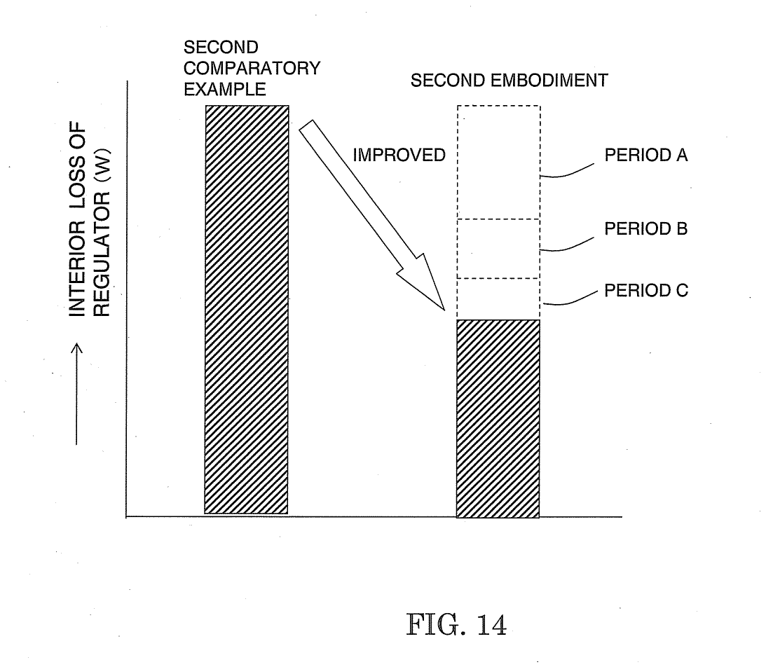

The internal losses which occur in the regulators of the second embodiment and the second comparative example will be described with reference to FIGS. 13 and 14. FIG. 13 illustrates a relationship between input voltages and output voltages of the regulators. FIG. 14 illustrates an internal losses of the regulators.

As illustrated in FIG. 13, the regulator 26a according to the second comparative example receives the boosted voltage Vcp1 as the power-supply voltage. The regulator 26a drops the boosted voltage Vcp1 to generate a plurality of dropped voltages Vreg0, . . . , Vregn having different values.

In contrast, the regulator 26 according to the present embodiment is as follows. In a region of a period A in which the dropped voltage is relatively low, the regulator 26 receives, as the power-supply voltage, the boosted voltage Vcp4 lower than the boosted voltage Vcp1. The boosted voltage Vcp4 is a lowest voltage. The regulator 26 drops the boosted voltage Vcp4 to generate a plurality of dropped voltages Vreg0, . . . , Vregf having different values.

In a period B when the dropped voltage is relatively higher than in the period A, the regulator 26 of the present embodiment receives, as the power-supply voltage, the boosted voltage Vcp3 higher than the boosted voltage Vcp4. The regulator 26 drops the boosted voltage Vcp3 to generate a plurality of dropped voltages Vreg(f+1), . . . , Vregk having different values which are higher than the boosted voltage Vcp4.

In a period C when the dropped voltage is relatively higher than in the period B, the regulator 26 of the second embodiment receives, as the power-supply voltage, the boosted voltage Vcp2 higher than the boosted voltage Vcp3. The regulator 26 drops the boosted voltage Vcp2 to generate a plurality of dropped voltages Vreg(k+1), . . . , Vregm having different values which are higher than the boosted voltage Vcp3. In a period D, the input voltages Vin provided to the regulator 26 of the second embodiment and the regulator 26a of the second comparative example are the same, i.e., the boosted voltage Vcp1.

The following equations represent an internal loss Ross11 of the regulator 26 of the second embodiment in the period A, an internal loss Ross11a of the regulator 26a of the second comparative example in the period A, an internal loss Ross12 of the regulator 26 of the second embodiment in the period B, an internal loss Ross12a of the regulator 26a of the second comparative example in the period B, an internal loss Ross13 of the regulator 26 of the second embodiment in the period C, and an internal loss Ross13a of the regulator 26a of the second comparative example in the period C, respectively. In the equations below, Iout1 to Iout3 denote output currents respectively.

Ross11=(Vcp4−Vregi)×Iout1 (10)

Ross11a=(Vcp1−Vregi)×Iout1 (11)

Ross12=(Vep3−Vregi)×Iout2 (12)

Ross12a=(Vcp1−Vregi)×Iout2 (13)

Ross13=(Vcp2−Vregi)×Iout3 (14)

Ross13a=(Vcp1−Vregi)×Iout3 (15)

In a case that the output currents Iout1 to Iout3 are the same value, the following equations represent an improvement amount ΔRoss11 of the internal loss of the regulator 26 of the second embodiment in the period A, an improvement amount ΔRoss12 of the internal loss of the regulator 26 of the second embodiment in the period B, and an improvement amount ΔRoss13 of the internal loss of the regulator 26 of the second embodiment in the period C, respectively.

ΔRoss11=(Vcp1−Vcp4)×Tout (16)

ΔRoss12=(Vcp1−Vcp3)×Tout (17)

ΔRoss13=(Vcp1−Vcp2)×Tout (18)

ΔRoss11>ΔRoss12>ΔRoss13 (20)

FIG. 14 illustrates decrease of internal loss of the regulator 26 according to the amounts of improvement as described above.

As described above, in the semiconductor memory device 90 according to the second embodiment, the boosted voltages Vcp1 to Vcp4 provided from the booster circuits 22 to 25 are selectively provided to the regulator 26 via the switches SW11 to SW14.

Accordingly, the booster circuit 22 which consumes a largest power may be used less frequently, and the average power consumption in the semiconductor memory device 90 can be greatly reduced. Further, the difference between the input voltage and the output voltage of the regulator 26 can be reduced. Thus, the internal loss of the regulator 26 can be greatly improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, in the embodiments, each memory cell of the memory array 11, 31 stores four values (2 bits). Alternatively, each memory cell may store eight values (3 bits), sixteen values (4 bits), or two values (1 bit).

In the first embodiment, a NOR flash memory is employed. In the second embodiment, a NAND flash memory is employed. Instead of these memories, an MRAM (magnetic random access memory), PRAM (phase-change random access memory), ReRAM (resistance random access memory) or FERAM (ferroelectric random access memory) may be employed.

In the second embodiment, dropped voltages generated by the regulator 26 are provided to a selected word line (WL). Another regulator may be provided, and the regulator may receive a plurality of boosted voltages so as to generate dropped voltages for setting a voltage of a bit line (BL). Further another regulator may be provided, and the regulator may receive a plurality of boosted voltages so as to generate dropped voltages for setting a voltage of an unselected word line.

In each embodiment, a semiconductor memory device is employed. Instead of the semiconductor memory device, various kinds of semiconductor integrated circuit devices having a regulator may be employed.

In each embodiment, three or four booster circuits are used, but two or more booster circuits may be used.

What is claimed is:

1. A semiconductor integrated circuit device comprising:
a plurality of booster circuits each of which receives an input voltage, boosts the input voltage, and generates a boosted voltage having a different value;
a regulator capable of generating a plurality of dropped voltages by dropping each boosted voltage from the booster circuits; and
a plurality of switches connected between the booster circuits and the regulator, the switches selectively providing the boosted voltages outputted from the booster circuits to the regulator as a power-supply voltage.

2. The semiconductor integrated circuit device according to claim 1, further comprising a regulator control circuit configured to generate switching signals for switching the switches.

3. The semiconductor integrated circuit device according to claim 2, wherein the regulator control circuit further generates an output voltage control signal for setting values of the dropped voltages to be generated by the regulator.

4. The semiconductor integrated circuit device according to claim 3, wherein the regulator control circuit further generates a regulator control signal for controlling operation of the regulator.

5. The semiconductor integrated circuit device according to claim 3 further comprising a mode control circuit configured to generate control signals for controlling boosting each input voltage and for generating an operation mode control signal for controlling the regulator control circuit.

6. The semiconductor integrated circuit device according to claim 3, wherein the regulator includes a current mirror circuit, a variable resistor unit connected to an output node of the current mirror circuit, and two comparators for receiving voltages from the variable resistor unit as a feedback and for providing output signals to two input terminals of the current mirror circuit, and
wherein the boosted voltages are selectively provided by the switches to the current mirror circuit as the power-supply voltage, and a resistance of the variable resistor unit is set based on the output voltage control signal, so that a dropped voltage can be outputted from the output node.

7. The semiconductor integrated circuit device according to claim 6, wherein the regulator further includes a transistor connected to the output node and switched based on the regulator control signal.

8. The semiconductor integrated circuit device according to claim 3, wherein the switches are switched so that ON-periods do not overlap with each other.

9. The semiconductor integrated circuit device according to claim 1, further comprising a memory unit, wherein the regulator is connected to the memory unit, and the voltage dropped by the regulator can be provided to the memory unit.

10. The semiconductor integrated circuit device according to claim 9, wherein the dropped voltage is provided to a selected word line of the memory unit.

11. The semiconductor integrated circuit device according to claim 9, wherein the dropped voltage outputted from the regulator is used for at least one of rewriting, writing, step-up writing, writing verification, reading, and erasing verification operations for a memory cell in the memory unit.

12. The semiconductor integrated circuit device according to claim 9, wherein the memory cell is constituted by at least one of a NOR flash memory, a NAND flash memory, an MRAM, a PRAM, a ReRAM, and an FeRAM.

13. The semiconductor integrated circuit device according to claim 1, wherein each of the booster circuits includes a charge pump circuit.

14. The semiconductor integrated circuit device according to claim 5, wherein each of the booster circuits includes a charge pump circuit, and each of the control signals given by the mode control circuit is provided to each charge pump circuit via at least one inverter.

15. The semiconductor integrated circuit device according to claim 14, wherein the charge pump circuit includes a transistor and a capacitor.

16. The semiconductor integrated circuit device according to claim 9, wherein a memory cell transistor of the memory cell unit stores information of two bits or more.

17. The semiconductor integrated circuit device according to claim 9, wherein a boosted voltage lower than the highest boosted voltage among the boosted voltages outputted from the booster circuits can be selected and used as the power-supply voltage for the regulator in order to obtain a dropped voltage needed for the memory cell.

18. The semiconductor integrated circuit device according to claim 17, wherein a boosted voltage which is higher than a voltage needed by the memory cell unit but is the lowest among the boosted voltages can be selected and used as the power-supply voltage for the regulator.
